(19) United States
(12) Patent Application Publication
(10) Pub. No.: US 2013/0271166 A1
(43) Pub. Date: Oct. 17, 2013

(54) Dielectric Monitoring System and Method Therefor

(71) Applicant: WICOR AMERICAS INC., (US)

(72) Inventors: Riley H. Bouffard, St. Johnsbury, VT (US); Russell W. Hayes, St. Johnsbury, VT (US); Anh N. Hoang, San Jose, CA (US)

(73) Assignee: WICOR AMERICAS INC., Hanover, NH (US)

(21) Appl. No.: 13/646,442

(22) Filed: Oct. 5, 2012

Related U.S. Application Data
(60) Provisional application No. 61/543,434, filed on Oct. 5, 2011.

(51) Int. Cl. G01R 31/14

(52) U.S. Cl. CPC G01R 31/14
USPC 324/750.01

(57) ABSTRACT

A system and method for monitoring or testing dielectric material nondestructively and in situ within field-based electrical equipment or as samples in a laboratory environment. In exemplary embodiments the use of negative voltage test pulses and a ground plane electrode with a parabolic curve or ogive shape minimizes energy transferred to the dielectric material to avoid or minimize degradation of the material. The disclosed system and method are thus suitable, inter alia, for continuous or near-continuous monitoring of fluid-filled electrical equipment in the field.

### RELATED APPLICATION DATA

This application claims the benefit of priority of U.S. Provisional Patent Application Ser. No. 61/543,434, filed Oct. 5, 2011, and titled “Dielectric Monitoring System and Method Therefore,” which is incorporated by reference herein in its entirety.

### FIELD OF THE INVENTION

The present invention generally relates to the field of dielectric material testing and monitoring and more specifically to monitoring of electrical devices containing dielectric material. In particular, embodiments of the present invention are directed to dielectric fluid monitoring systems and methods therefore.

### BACKGROUND

Many electrical devices, for example power transformers, use a dielectric material, often a liquid such as silicone, mineral oil, or vegetable oil, to prevent voltage arcing between conductors and to aid in the removal of heat generated by the conductors during operation. In other applications solid or gas dielectric materials may be used. Due to temperature changes within an electrical device, events that occur within the device, e.g., faults, water, oxygen, and other contaminant ingress, etc., the dielectric material may degrade and loses its ability to adequately insulate the voltage and dissipate heat. Moreover, the degradation enhances the risk of an electrical device failure.

To reduce the possibility of electrical device failure, regular inspections of the dielectric material are typically performed in order to test its dielectric condition. An inspection typically involves the manual extraction of a sample from within the electrical device and subsequent testing with a dielectric strength tester. As regards fluid dielectrics, typical testing apparatus applies an AC voltage stress to an electrode pair immersed in the fluid, with the stress being continuously increased until breakdown occurs, the breakdown being a measure of the ability of the material to perform its dielectric function. Unfortunately, these types of dielectric tests can be destructive to dielectric materials, so much so, that the tests are necessarily performed on a sample external to the electrical device, with the sample being discarded after the test. Additionally, because of the aforementioned laborious testing procedures, electrical device dielectric materials are analyzed on a routine having lengthy intervals between tests (e.g., annual or biannual tests), and generally without regard to the operating history of the electrical device. Thus, degradation may go undetected, resulting in failures of the electrical device.

### SUMMARY OF DISCLOSURE

In one implementation, the present disclosure is directed to a system for determining a state of a dielectric material used in dielectric-containing electrical equipment. The system includes a probe defining a gap configured to receive the dielectric material therein; and a pulse generator in electrical communication with the probe, the pulse generator configured to produce a negative voltage pulse at the gap.

In further embodiments, such a system may also include a control system in electronic communication with the pulse generator, with the control system configured to initiate generation of the negative voltage pulse by the pulse generator and to provide output indicative of the dielectric material state based on a return signal from the probe. The control system may comprise a processor configured to execute instructions to: direct the pulse generator to generate the negative voltage pulse; evaluate a signal from the pulse generator, the signal including information regarding a ground return from the probe resulting from at least a portion of the negative voltage pulse passing across the gap; and determine the dielectric material state including at least a breakdown time based upon the ground return signal.

In other alternative embodiments, the probe may comprise a needle and a ground plane with the gap defined therebetween. The ground plane may be ogive-shaped with the pointed end toward the gap. The ogive shape may comprise parabolic curves.

The negative voltage pulse may comprise a substantially square waveform and may be a variable pulse. The negative voltage may be between about −10 kV and about −30 kV or may be between about −15 kV and about −30 kV.

In further alternatives, the system may be configured to determine the state of a dielectric material that is a fluid and the fluid may be a liquid or gas. The dielectric material also may be a solid. The probe and the gap may be configured and dimensioned to receive a discrete sample of dielectric material, in which case a fluid is contained in a container.

In yet another alternative, the dielectric-containing electrical equipment comprises fluid-filled equipment and wherein the probe is configured and dimensioned to mount within the fluid-filled equipment in communication with the fluid contained therein. Such fluid-filled equipment may be a power transformer.

In another implementation, the present disclosure is directed to a system for determining a state of dielectric material in dielectric-containing electrical equipment. The system includes a probe configured and dimensioned to mount within the equipment in communication with the dielectric material contained therein, the probe including a needle and a ground plane; a pulse generator including a voltage multiplier, the voltage multiplier electronically coupled to the probe; and a control system in electronic communication with the pulse generator, wherein the control system includes instructions to direct the pulse generator to generate a substantially square negative voltage pulse; evaluate a signal from the pulse generator, the signal including information regarding a ground return resulting from at least a portion of the substantially square voltage pulse passing from the needle to the ground plane; and determine the dielectric material state including at least a breakdown time based upon the ground return signal.

In such an implementation, the dielectric material may be a fluid and the dielectric-containing electrical equipment may comprise fluid-filled equipment and the probe may be configured and dimensioned to mount within the fluid-filled equipment in communication with the fluid contained therein. Alternatively, the dielectric material is a solid.

In further alternatives, the needle and the ground plane may be disposed in an opposing relationship so as to form a gap therebetween. The probe may have an adjustable gap width and the ground plane may have a parabolic shape. The ground plane may comprise a parabolic ogive. In such a system, the pulse generator may sense the ground return via the ground plane.

In another alternative embodiment, the pulse generator includes a power supply, and the power supply is electronically coupled to the voltage multiplier so as to direct an AC voltage or a pulsed DC voltage to the voltage multiplier. The voltage multiplier may comprise a ladder network of capacitors and diodes. Further, the pulse generator may produce a variable negative voltage pulse, which may be between about −10 kV and about −30 kV or between about −15 kV and about −30 kV.

In yet another implementation, the present disclosure is directed to a method for testing a dielectric fluid within fluid-filled equipment, wherein the equipment includes a probe having a needle and a ground plane diametrically opposed within so as to form a testing gap. The method includes generating a negative voltage waveform having a substantially square profile; sending the voltage waveform to the needle; monitoring for a ground return of at least a portion of the voltage through the testing gap to the ground plane; determining, when the monitoring indentifies the ground return, a time the ground return occurred. The method may further comprise determining a condition of the dielectric fluid based on said determining a time.

In yet another implementation, the present disclosure is directed to a method for testing a dielectric fluid within a power transformer. The method includes delivering a negative DC voltage with a predetermined waveform to a probe positioned in the dielectric fluid inside the power transformer; monitoring for a ground return at an electrode disposed in the dielectric fluid in the transformer at a predetermine distance from the probe; and determining, when the monitoring indentifies the ground return, a time the ground return occurred.

In yet another implementation, the present disclosure is directed to a method for testing dielectric material. The method includes a relatively positioning the dielectric material within a gap formed by a needle electrode and ground plane; generating a negative voltage waveform having a substantially square profile; sending the negative voltage waveform to the needle; monitoring for a ground return of at least a portion of the negative voltage through the gap to the ground plane; measuring, when the monitoring indentifies the ground return, a time the ground return occurred; and determining a condition of the dielectric material based on the measured time.

In alternative embodiments of such an implementation the needle electrode and ground plane may comprise a probe and the relatively positioning comprise mounting the probe within a dielectric-containing electrical equipment. In such an embodiment, the dielectric material may be a fluid.

In further alternatives, such a method further comprises forming the ground plane with a parabolic curve, and the parabolic curve may comprise an ogive-shaped electrode. In other alternatives the negative voltage is between about −10 kV and about −30 kV or between about −15 kV and about −30 kV. And in further alternative embodiments the dielectric material may be a fluid or a solid, wherein the fluid may be a liquid or gas. Also, the relatively positioning may comprise placing a discrete sample of dielectric material with the gap.

In yet another alternative, the adjusting is based on at least one of the type of dielectric material, a type of equipment using the dielectric material, a point in the life-cycle of the equipment and/or the determining comprises correlating the measured time to predetermined dielectric material states.

In certain embodiments, such a method may comprise a method for monitoring dielectric material state, which would further comprise steps of instructing generation of the negative voltage wave form with a predetermined pulse length, determining if a ground return received in less time than the predetermined pulse length, when no ground return is received, identifying a good state for the dielectric material and instructing a new generation step at a first predetermined frequency interval, when a ground return is received in a time less than the predetermined pulse length but greater than a second time value greater than zero, identifying a caution state for the dielectric material and instructing a new generation step at a second predetermined frequency interval, when a ground return is received in a time less than the second time value, identifying an alert state for the dielectric material. Additionally, the method may comprise, when an alert state is identified, instructing a new generation step at a third predetermined frequency interval. The first predetermined frequency interval may be the same as the second predetermined frequency interval and the first predetermined frequency interval may be greater than the second predetermined frequency interval.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a schematic representation of an exemplary embodiment of a monitoring system used in an electrical device, in this case a power transformer, according to an embodiment of the present invention;

FIG. 2 is a graph of a voltage versus time for a dielectric material undergoing a breakdown event when using a monitoring system according to an embodiment of the present invention;

FIGS. 3A and 3B are graphical representations of two sets of five test pulses transmitted to a dielectric material using an embodiment of the present invention, with time represented on the x axis and voltage represented on the y-axis.

FIG. 4 is a flow chart illustrating an exemplary process for monitoring a dielectric material according to an embodiment of the present invention; and

FIG. 5 is a block diagram of a control system for use with a monitoring system according to an embodiment of the present invention.

### DETAILED DESCRIPTION

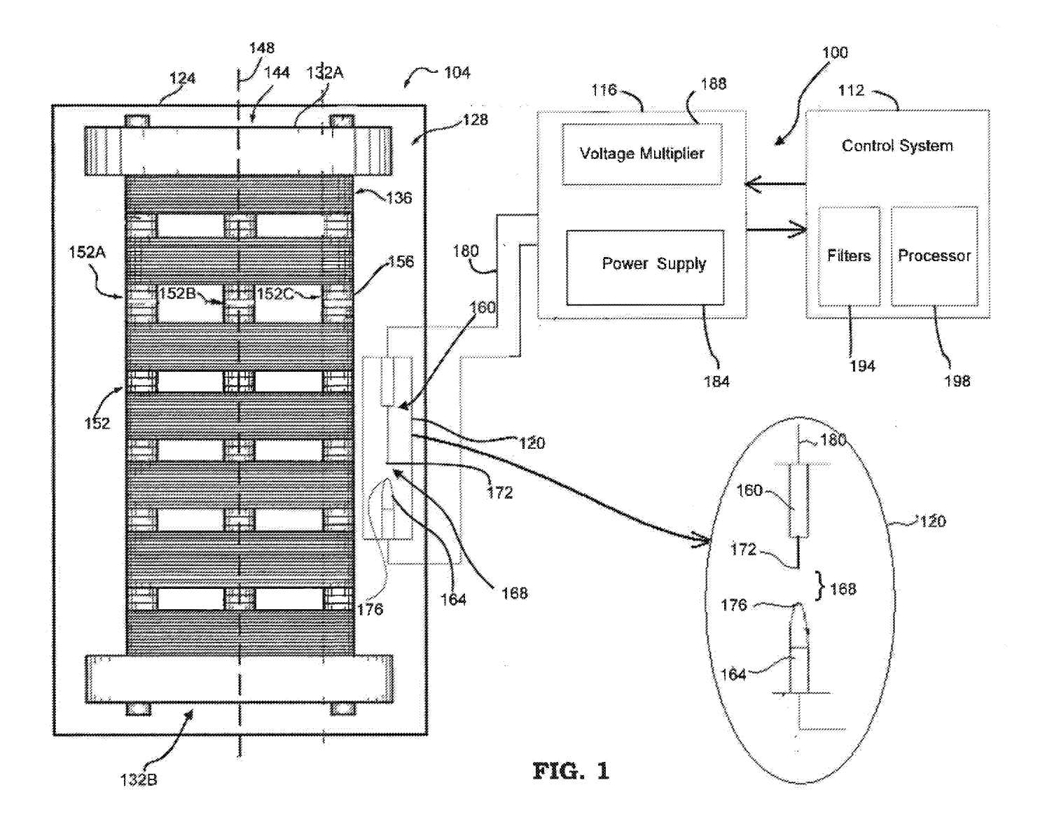

Referring now to the drawings, FIG. 1 illustrates an exemplary monitoring system 100 in accordance with certain aspects of the present invention for use with a dielectric-containing electronic device, such as, but not limited to, fluid-filled power transformers, on-load tap changers, circuit breakers, and regulators. For ease of discussion, FIG. 1 illustrates an exemplary embodiment of the invention in terms of one such device, power transformer 104, that includes monitoring system 100.

As discussed more fully below, monitoring system 100 includes components necessary to directly measure and electronically communicate to a utility or other entity, information related to the condition of a dielectric material contained within the device without having to manually remove and test the dielectric material. This information may be used to determine where dielectric material is along its life-cycle, its current condition, and if precautionary or corrective actions should be taken in a way that minimizes operational risk, avoids costs associated with forced power outages, and increases the useful life of the transformer.

In the exemplary embodiment shown in FIG.1, monitoring system 100, using control system 112 and pulse generator 116, generates and transmits a precise voltage for a precise amount of time to a probe 120 within any dielectric material containing electrical equipment, such as power transformer 104, and reports the condition of the dielectric material, including whether and when a breakdown of dielectric material occurs.

As shown in FIG. 1, exemplary power transformer 104 includes a transformer tank 124, into which a winding assembly 128 is positioned. Transformer tank 124 is typically a water resistant container that, in certain embodiments of power transformer 104, holds a dielectric material, in this case a fluid/liquid, which may be, but is not limited to, mineral oil, silicon, vegetable oils, or other fluids suitable for insulating the conductors within the transformer, dissipating heat generated during the operation of the transformer, and mitigating water migration toward winding assembly 128.

Winding assembly 128 includes a pair of end blocks 132, i.e., end blocks 132A-B, with a plurality of windings 136 and a plurality of insulation assemblies 152 disposed between the end blocks. End blocks 132A-B are positioned in opposing relationship and are sized and configured to evenly distribute a clamping force from clamping assembly 144 along longitudinal axis 148 of power transformer 104. Windings 136 are typically formed around at least a portion of a magnetic core (not shown) and include multiple turns of a metal conductor, such as copper or aluminum. Each winding 136 may be wrapped around the magnetic core in a circular disc, helical, or layered pattern, or other wrapping pattern known in the art. Each winding 136 may be spaced apart by one or more radially arranged and circumferentially spaced insulation assemblies 152.

Insulation assemblies 152 may include one or more insulation plates 156 stacked on top of one another. Insulation assemblies 152 are sized and configured so as to aid in the distribution of the clamping force from end block 132A, through windings 136, to end block 132B. Insulation assemblies 152 also provide dielectric distance between windings 136 to prevent short circuits, to maintain the mechanical integrity of winding assembly 128 during random (non-spontaneous) short circuit events, and to provide a path between the windings that allows a sufficient amount of dielectric fluid to circulate and remove heat from the windings. Insulation assemblies 152 are typically spaced equidistantly around the circumference of windings 136, extending radially from the center of power transformer 104. In the exemplary power transformer shown in FIG. 1, six insulation assemblies 152 are located between each of windings 136 and are spaced about 60 degrees apart (FIG. 1 shows three of these insulation assemblies, i.e., assemblies 152A, 152B and 152C). As will be understood by persons of ordinary skill in the art, the number and positioning of insulation assemblies 152 may be chosen so as to appropriately distribute the clamping force throughout winding assembly 128.

Insulation plates 156 as used in a power transformer of the type exemplified in FIG. 1 are often constructed of cellulose, and are typically capable of absorbing dielectric fluid when placed in a dielectric fluid bath. Insulation plates 156 may also be a fiber composite having a combination of fibrous reinforcement, aramid fibers, polymers, and additives, which may give the insulation plates superior resistance to corrosion, chemicals, and high temperatures. In an embodiment, insulation assembly 152 includes a number of insulation plates 156 that is sufficient in number to prevent short circuiting of power transformer 104 during a fault event within an expected range. It will, however, be appreciated by persons of ordinary skill in the art that the power transformer illustrated in FIG. 1 is but one of many types of dielectric containing electrical equipment for which embodiments of the present invention may be employed.

As shown in FIG. 1, the electrical device (exemplary power transformer 104) includes a portion of monitoring system 100, probe 120, within the device itself, in this case within transformer tank 124. Probe 120 may generally be placed anywhere within an electrical device so as to be in proper communication with and to measure the condition of dielectric material contained therein. In an exemplary embodiment, the placement of probe 120 is determined based upon an analysis of where dielectric material is most likely to be contaminated or to suffer degradation and based upon the proximity of other high voltage components within the device.

In the exemplary embodiment shown in FIG. 1, probe 120 includes needle 160 and ground plane 164, with the needle and the ground plane being separated by gap 168. Needle 160 can facilitate the delivery of a high voltage charge to the dielectric material at a precise location and may be made of several materials and by methodologies known in the art. In an exemplary embodiment, needle 160 has point 172 with a diameter about 50 to about 100 microns and is made from tungsten carbide. In an alternative embodiment, needle 160 is made from hardened steel.

Ground plane 164 serves to receive the voltage transmitted by needle 160. In an exemplary embodiment, ground plane 164 is ogive-shaped, with narrowed end 176 directed toward point 172. The ogive shape of ground plane 164 provides a specifically, curved-shaped ground plane electrode to create focused electrical field. In a preferred embodiment, the curved shape is parabolic, or based on a parabolic ogive. The needle to parabolic ground plane electrode assembly creates a focused electric field, localizing breakdowns to a high field and medium voltage region. This allows for increased sensitivity and with reduced energy delivered to the test material upon breakdown, thus further reducing degradation as a result of testing. As with needle 160, ground plane 164 may be made from tungsten carbide, harden steel, or other metals suitable for withstanding the high voltage operating environment used with monitoring system 100.

The design of probe 120 is such that dielectric material is received within gap 168; in the case of a fluid dielectric, flows through gap 168. The size of gap 168 is dependent upon, among other things, the type of dielectric material used with the equipment, the type of equipment and the amount of voltage to be supplied to the dielectric material. In exemplary embodiments, gap 168 is sized such that a dielectric breakdown of the material does not occur when the dielectric material is known to be in a good condition (e.g., when the dielectric material is new or otherwise confirmed to be in good condition). In one exemplary embodiment, for a power transformer as shown in FIG. 1, using mineral oil as the dielectric material, gap 168 may be about 0.1 to about 0.4 mm. In alternative embodiments, depending on device parameters as may be determined by persons of ordinary skill in the art, gap 168 may be less than about 0.1 mm, but generally will not be less than about 0.08 mm, or in an overall range of about 0.08 mm to about 0.4 mm. In another alternative embodiment, probe 120 may be configured such that gap 168 has an adjustable width, which can be adjusted to a specific width based on the nature of the particular equipment to be monitored and the material to be tested. Factors such as different points within the life-cycle of the equipment being monitored may also be considered in selecting a specific gap width. Preferably the gap may be locked in place upon installation. Such adjustment may be achieved by providing for movement and locking of either or both of ground plane 164 and needle 160.

Pulse generator 116 provides a voltage to probe 120 via voltage input line 180. Pulse generator 116 receives power from a voltage source (not shown) and multiplies the voltage to a desired level for output to probe 120. In an exemplary embodiment, pulse generator 116 produces a negative voltage having a square waveform of a predetermined duration. As shown in FIG. 1, pulse generator 116 can include a power supply 184 and a voltage multiplier 188. Power supply 184 is suitable for providing conditioned low level AC power or pulsed DC power, e.g., 110 volts AC or DC, to voltage multiplier 188 and is typically connectable to an external power source (not shown).

Voltage multiplier 188 generates high DC voltage from the low voltage provide by power supply 184. In one exemplary embodiment, as will be appreciated by persons of ordinary skill in the art, voltage multiplier 188 may be made up of a voltage multiplier ladder network of capacitors and diodes. Using only capacitors and diodes, voltage multiplier 188 can step up relatively low voltages to the high values required for testing dielectric strength of the dielectric material. In an exemplary embodiment, voltage multiplier 188 provides an output voltage of between about −10 kV and about −30 kV, in some embodiments between about −15 kV and about −30 kV. Among other advantages, variable pulse magnitude capability permits testing and monitoring of multiple materials in multiple applications or equipment using the same system.

A negative square pulse as used in exemplary embodiments of the present invention helps to keep the plus signal as clean as possible. Negative pulses across the needle-to-plane electrode configuration demonstrate a pulse free mode that helps prevent energy being released into the system prior to breakdown. The square pulse is used to quickly expose the oil to a preset voltage and quickly turn it off in case of a breakdown avoiding any overshoot voltages.

Power supply 184 and voltage multiplier 188 both get instructions from control system 112. Control system 112 is configured to instruct pulse generator 116 to generate an output voltage pulse as described above with a certain magnitude for a certain amount of time, for example, 500 nanoseconds. In general the pulse length will be a positive time greater than zero and equal to or less than about 500 nanoseconds. In an exemplary embodiment, control system 112 receives instructions (discussed in more detail below) regarding the desired output voltage and pulse length and directs power supply 184 to provide a square voltage waveform of that magnitude and duration to voltage multiplier 188. The output of voltage multiplier 188 is transmitted on voltage input line 180 for use by probe 120. In some embodiments, the control system may instruct the pulse generator to generate a pulse with a length between about 100 and 500 nanoseconds. However, while the system may permit selection of different pulse lengths, the pulse length will most typically be fixed at a specific time for a particular equipment monitoring or test routine.

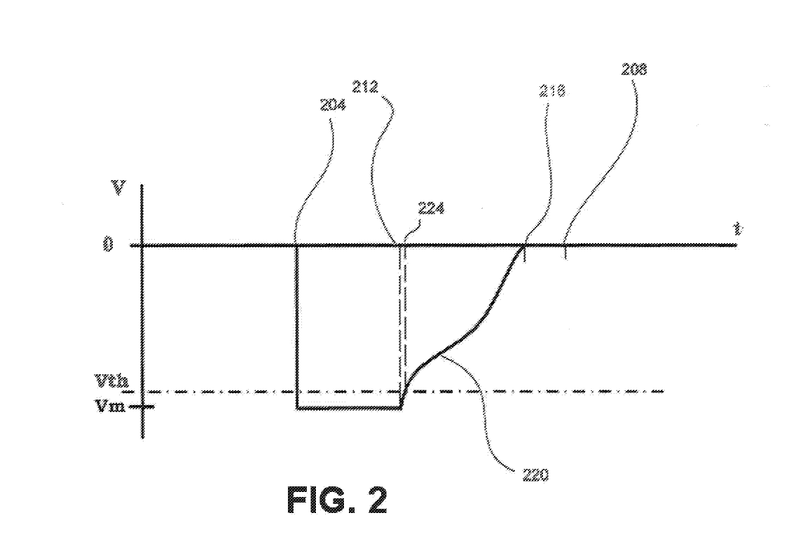

Control system 112 also receives one or more signals containing information related to breakdown events that occur across gap 168. In an exemplary embodiment, control system 112 senses for a ground return, which is the passage of voltage from needle 160, across gap 168, to ground plane 164. The sensing by control system 112 may occur continuously or nearly continuously thereby improving the accuracy of identifying the beginning of a breakdown event (e.g., initial breakdown time 212, FIG. 2, discussed in detail below).

In an exemplary embodiment, pulse generator 116 may be encased in a protective box suitable for containing a high voltage device. The components of pulse generator 116 may also be immersed in a high voltage potting compound. Exemplary potting compounds include resins, including, but not limited to, epoxies and silicones.

As noted above, control system 112 provides instructions to pulse generator 116 regarding the magnitude and duration of the voltage to be delivered to probe 120. The instructions delivered by control system 112 can be based on inputs by a user, from preprogrammed instructions, and/or based upon feedback received from pulse generator 116. For example, control system 112 may receive a signal from pulse generator 116 indicating a breakdown event occurred at a certain time. If the certain time is within a determined timeframe, control system 112 may increase the frequency of testing of the dielectric material so as to more closely monitor the condition of the material.

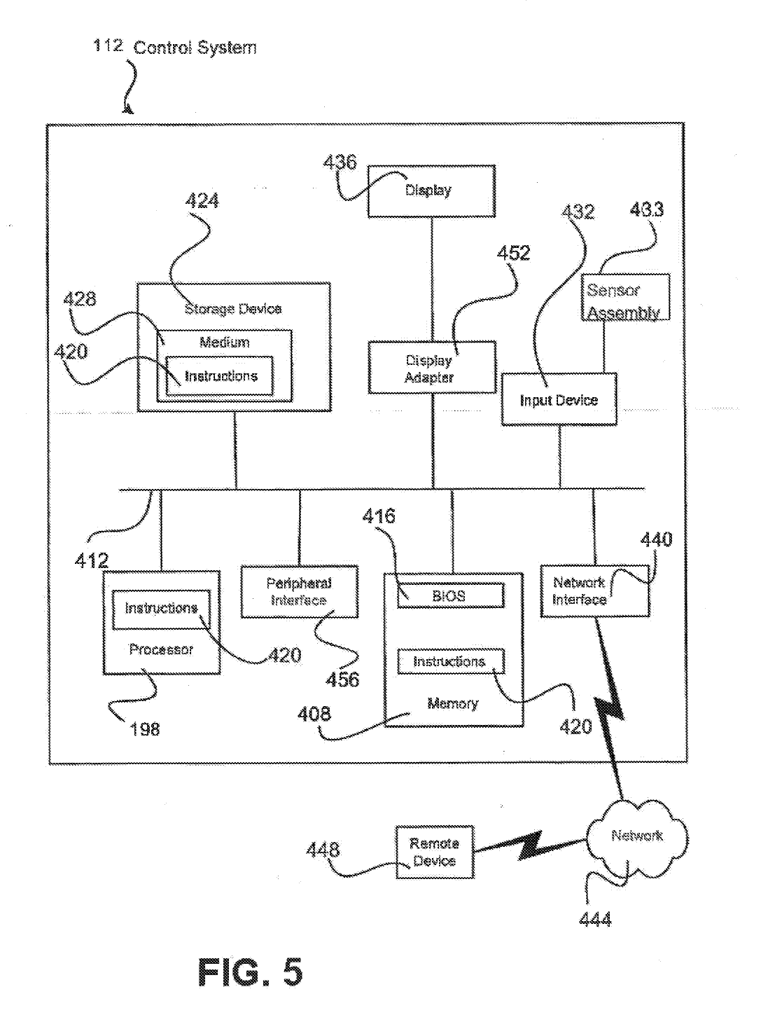

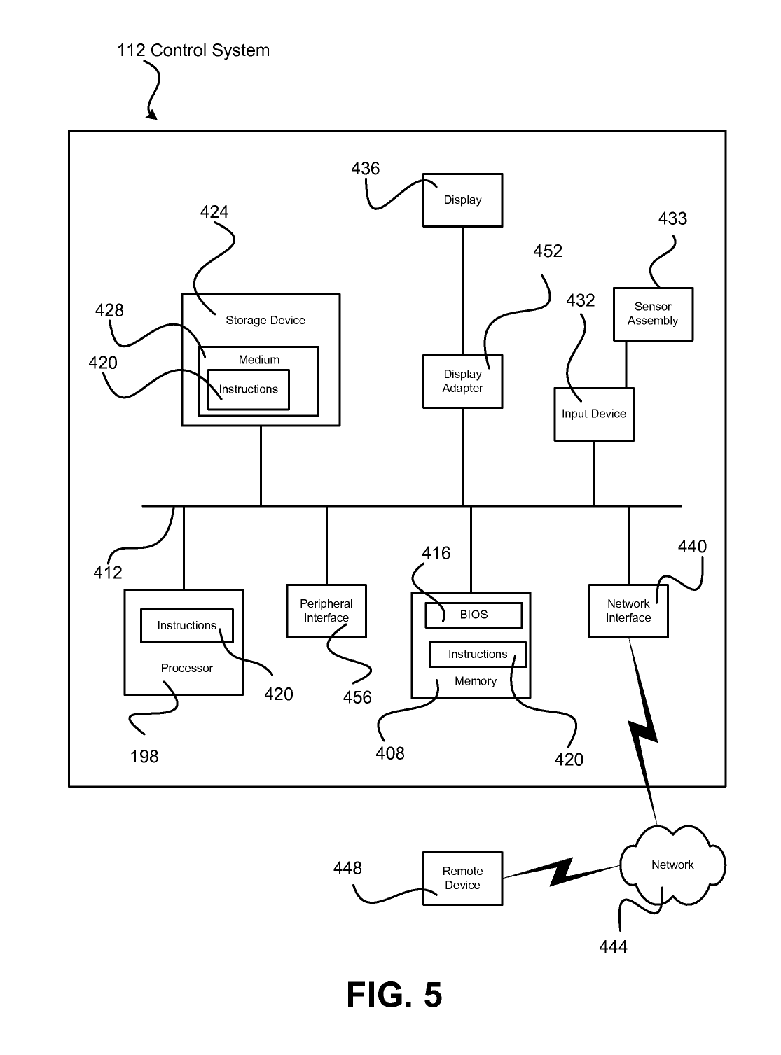

In an exemplary embodiment, control system 112 can also include, among other things, one or more filters 194 for conditioning the incoming information from pulse generator 116, and processor 198. In an alternative embodiment, some or all of control system 112 may be combined with pulse generator 116. More details of an exemplary control system are discussed below in connection with FIG. 5.

Processor 198 is capable of receiving breakdown information from pulse generator 116. In an exemplary embodiment, the pulse generator provides a digital signal and an analog signal, the signals containing information related to the breakdown event. In such an embodiment, processor 198 compares the two signals. Comparing the two signals can lead to increased accuracy in determining the time of dielectric breakdown. From the information contained on one or both of the signals, processor 198 then determines a breakdown time, which is the length of time the voltage coming from pulse generator 116 has been applied to dielectric material before the pulse generator sensed a ground fault return (i.e., voltage passing across gap 168 via the dielectric material to ground plane 164). The length of time to breakdown is an indicator of dielectric material condition in so far as dielectric material in poorer condition will break down earlier than dielectric material in better condition. The length of time to breakdown of dielectric material may be reported to an operator or may be part of an alert system, such as the alert system described below.

A test sequence in accordance with embodiments of the present invention, and resulting breakdown event if it occurs, may be represented in a graph of applied voltage over time, as shown in FIG. 2. In this example, voltage from pulse generator 116 is delivered to needle point 172 at time 204. Due primarily to the square waveform, the voltage delivered to the needle point at time 204 is about an instantaneously maximum voltage, Vm, corresponding to the minimum dielectric material breakdown voltage chosen for the given material. If there is no breakdown of dielectric material, the voltage at the needle point would be maintained to end time 208. However, in the example illustrated in FIG. 2, a breakdown of dielectric material begins at an initial breakdown time 212 and reduces the voltage potential across gap 168 to zero (0) at time 216 via a non-linear voltage reduction represented by breakdown line 220.

It should be noted that in contrast to prior art ASTM dielectric testing, which significantly degrades the oil sample, monitoring system 100, because of the extremely small quantity of electrical energy delivered to the material, due to the square waveform and the short duration of the voltage pulse does not degrade the dielectric material when the material is in good condition and minimizes the degradation of the dielectric material when a breakdown occurs. Thus, when a breakdown event occurs at the beginning of the pulse, the total pulse time will be less than pulse time instructed by the control system. Additionally, depending on the impedances used to generate the pulse, the overall energy available to be dissipated in the test cell can be less than 1 μJ, which is an amount that minimizes dissolved gas and does not appreciably reduce dielectric strength.

Although Vm in FIG. 2 is shown as constant, in some instances it may vary. To avoid false indications of dielectric breakdown that could occur as a result of identifying any deviation from Vm, the breakdown time of dielectric material can be determined at the time when breakdown line 220 crosses a threshold voltage value, Vth, which, in this embodiment, occurs at time 224. In an exemplary embodiment, threshold voltage value is equal to about 70 to 90% of Vm. In another embodiment it may be about 80% of Vm. Other values of Vth may be chosen depending on the desired sensitivity of monitoring system 100 to breakdowns of dielectric material.

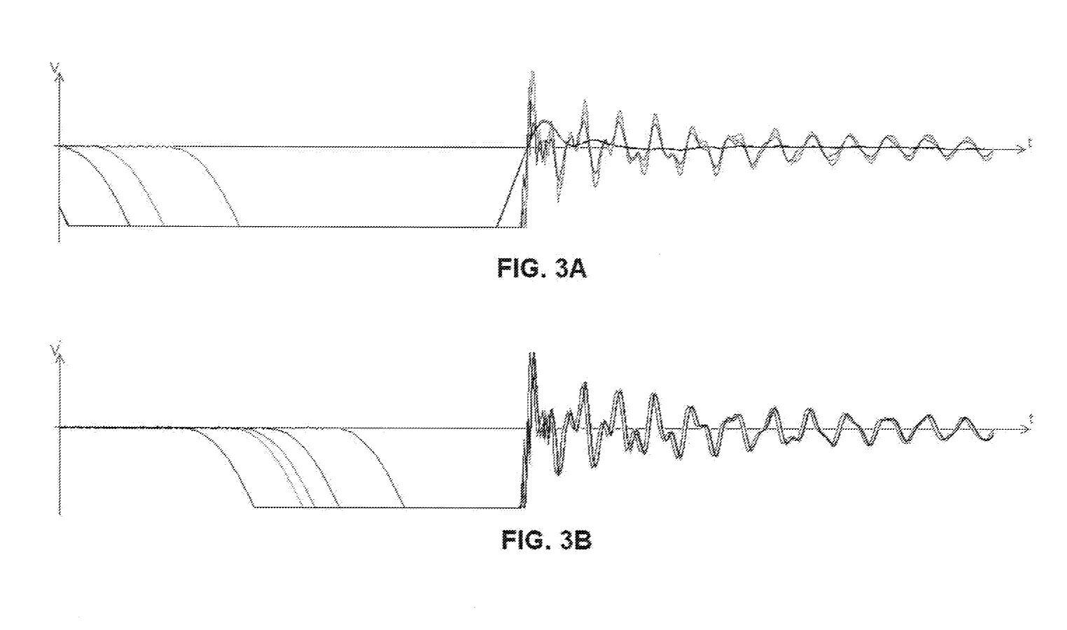

FIGS. 3A and 3B illustrate voltage over time based on data generated by an exemplary dielectric monitoring system as described using material samples with different contaminants. The data presented in FIG. 3A shows a measurable shift in damping coefficient as metallic particles are introduced into the test sample, in this case mineral oil. The data presented in FIG. 3B shows a subtle, but measurable shift in frequency as moisture is added to a separate test sample, again mineral oil. These graphs not only show the flatness of the square pulse and the rapidity of voltage fall and rise, but also resonant ringing after breakdown.

Mathematically, the resonant ringing frequency of the probe circuit can be stated by the equation:

ω₀=1/√(L C) [1]

Where L is the inductance of gap 168 and C is the capacitance of gap 168. The damping of the ringing of the circuit is given by the equation:

γ=(1/(2 R))√(L/C) [2]

Where R is the resistance of gap 168. As various contaminants present in the dielectric material may possess varying levels of electrical resistance, capacitance, and inductance, it is possible to relate the measured frequency and damping coefficient of periodic ringing after a breakdown with general categories of contaminants present near the probe. For example, certain metallic contaminants are known to have a higher inductance than water, as well as a lower resistance and lower capacitance. The higher inductance may cause a higher damping coefficient to be observed if certain metallic contaminants are responsible for the breakdown, in comparison with water contamination resulting in the loss of material insulating quality.

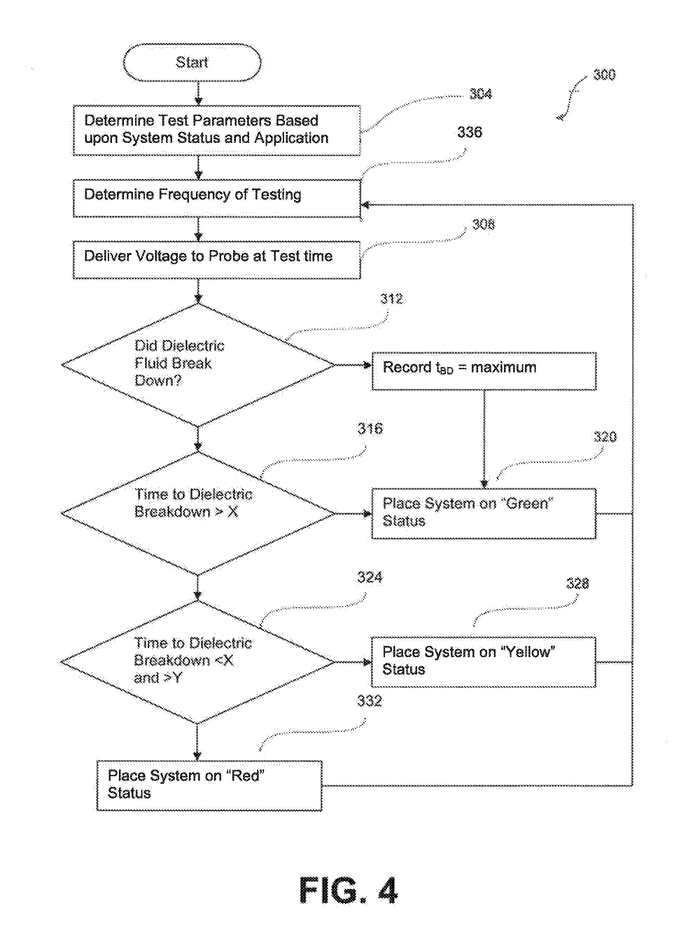

FIG. 4 shows an exemplary process 300 for monitoring a dielectric material according to embodiments of the present invention. Such a process may be based on a system including related hardware and software that provides instructions to a grid or other operator based on dielectric force breakdown measurements. Software or firmware instructions for implementing the process illustrated in FIG. 4 may be executed by control system 112, described more below and illustrated in FIG. 5. Turning to FIG. 4, at step 304, parameters such as a maximum voltage value corresponding to the desired minimum dielectric breakdown resistance value, an indicator of dielectric material condition, are determined. The minimum dielectric breakdown value will vary by kind of dielectric material used within any piece of equipment, such as electrical device 104.

At step 308, the voltage determined in step 304 is delivered to a probe, such as probe 120, within the transformer. As discussed above, delivery of the voltage is initiated by control system 112, which directs a pulse generator, such as pulse generator 116 to produce a voltage of a certain magnitude for a certain duration.

At step 312, a determination is made as to whether a dielectric material breakdown occurred. If not, the system will report a “Green” status (“good state”) and wait until the predetermined test protocol requires further testing to be performed. If a breakdown is detected to have occurred, the system proceeds to step 316.

At step 316, the time at which the breakdown occurred is determined. In an exemplary embodiment, the time to breakdown is determined through the consistent reporting of whether a ground return is sensed by pulse generator 116, which indicates that the voltage potential across gap 168 is decreasing and thus the dielectric material is experiencing a breakdown. Depending on the time to the breakdown, the monitoring system may indicate the dielectric material condition by providing a status of the material. In the exemplary embodiment of process 300 shown in FIG. 4, if the breakdown of dielectric material occurs after a predetermined time X, which depends on the type of equipment tested and the nature of the dielectric material, the process can proceed to step 320 where the system is placed on “Green” status. After setting the system on “Green” status, the process returns to step 308 or 336 (alternative discussed later) for continued measurement of the dielectric material breakdown times. In an alternative embodiment, after setting the system on “Green” status after an earlier “Yellow” (“caution state”) or “Red” status (“alert state”) indication, the monitoring system may less frequently test the dielectric material. If the breakdown of the dielectric material occurs prior to X, indicating a more degraded condition of the dielectric material, the process continues to step 324.

At step 324, the time to breakdown of the dielectric material is evaluated to determine extent of degradation, as quicker breakdown times may require different responses by an operator. Depending on the speed of the breakdown of the dielectric material, the system may be placed in a “Yellow” status at step 328 or a “Red” status at step 332. “Yellow” status can indicate, among other things, that precautionary measures should be taken, such as scheduling an outage for the transformer in order to replace dielectric material. “Red” status can indicate, among other things, that the condition of dielectric material has decreased below a predetermined level and/or that the condition of the dielectric material has increased the probability of failure of the transformer. In one exemplary embodiment of process 300, the system is set to “Red” status if, at step 324, the time to breakdown is less than a time X, but greater than an earlier time Y. In an exemplary embodiment, X and Y are parameters determined in accordance to the nature of the electrical equipment and the nature of the dielectric material.

Regardless of the parameters such as X and Y employed, after placing the system in a “Yellow” status, the process returns to step 308 or 336 (alternative discussed later) to continue measuring the condition of dielectric. The system may also be placed in “Yellow” status based on predefined criteria. For example, the system may also be placed in “Yellow” status when the time to breakdown has decreased by a certain amount of time over a certain period, e.g., one month. As a result of being placed in a “Yellow” status, in an embodiment, process 300 may increase the frequency of testing of dielectric material. Upon being placed in a “Yellow” status, the frequency of testing may be increased or decreased to provide higher resolution of historical data, particularly in the latter example, when the quality of the dielectric material is believed to be changing more rapidly.

The system may be placed in “Red” status based on several different criteria. For example, and as shown in FIG. 4, if the time to breakdown of the dielectric material has fallen to less than earlier time Y, the system may be placed in “Red” status at step 332. As another example, the system may be placed in “Red” status if the measured time to breakdown between sequential measurements has fallen by more than a predetermined value over a predetermined period. Notably a steep reduction in a relatively short amount of time may suggest to the operator that the reduction in the dielectric material condition may have occurred because of an ingress of contamination, such as water, and further investigation may be justified to determine if there are further problems with the transformer. As a result of being placed in a “Red” status, in an embodiment, process 300 may increase the frequency of testing of the dielectric material when placed in “Red” status.

An alternative embodiment of process 300 includes step 336, which determines the frequency of testing of the dielectric material. The frequency of testing can be based, at least in part, on the results of the previously performed testing. For example, if the system has been placed in a “Yellow” status, the process may increase the frequency of measurements of dielectric material so as to provide the utility or operator with more frequent status updates of the condition of the dielectric material. Changes in the frequency of monitoring of the dielectric material may be automated, for example, any frequency increases may be proportional to the time to breakdown measured or may be a step function. Changes in the frequency of monitoring may also be manual. For example, after the system status is updated, a user is prompted to enter the frequency of testing going forward.

It is to be noted that any one or more of the aspects and embodiments of process 300 and/or monitoring system 100, as described herein, may be conveniently implemented using one or more machines (e.g., one or more computing devices that are utilized as a user computing device) programmed according to the teachings of the present specification, as will be apparent to those of ordinary skill in the computer art. Aspects and implementations of monitoring system 100, discussed above, employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device, control system 112) or a portion of the machine (e.g., processor 198) and that causes the machine to perform any one of the methodologies and/or embodiments described herein. Examples of a machine-readable storage medium include, but are not limited to, a magnetic disk, an optical disk, a magneto-optical disk, a read-only memory “ROM” device, a random access memory “RAM” device, a magnetic card, an optical card, a solid-state memory device (e.g., a flash memory), an EPROM, an EEPROM, and any combinations thereof. A machine-readable medium, as used herein, is intended to include a single medium as well as a collection of physically separate media, such as, for example, a collection of compact disks or one or more hard disk drives in combination with a computer memory. As used herein, a machine-readable storage medium does not include a signal.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

FIG. 5 shows a diagrammatic representation of one exemplary embodiment of control system 112, within which a set of instructions for causing a processor 198 to perform any one or more of the aspects and/or methodologies of the present disclosure. It is also contemplated that multiple computing devices may be utilized to implement a specially configured set of instructions for causing monitoring system 100 to perform any one or more of the aspects and/or methodologies of the present disclosure.

Control system 112 can also include a memory 408 that communicates with processor 198, and with other components, via a bus 412. Bus 412 may include any of several types of bus structures including, but not limited to, a memory bus, a memory controller, a peripheral bus, a local bus, and any combinations thereof, using any of a variety of bus architectures.

Memory 408 may include various components (e.g., machine readable media) including, but not limited to, a random access memory component (e.g., a static RAM “SRAM”, a dynamic RAM “DRAM”, etc.), a read only component, and any combinations thereof. In one example, a basic input/output system 416 (BIOS), including basic routines that help to transfer information between elements within control system 112, such as during start-up, may be stored in memory 408. Memory 408 may also include (e.g., stored on one or more machine-readable media) instructions (e.g., software) 420 embodying any one or more of the aspects and/or methodologies of the present disclosure. In another example, memory 408 may further include any number of program modules including, but not limited to, an operating system, one or more application programs, other program modules, program data, and any combinations thereof.

Control system 112 may also include a storage device 424, such as, but not limited to, the machine readable storage medium described above. Storage device 424 may be connected to bus 412 by an appropriate interface (not shown). Example interfaces include, but are not limited to, SCSI, advanced technology attachment (ATA), serial ATA, universal serial bus (USB), IEEE 1394 (FIREWIRE), and any combinations thereof. In one example, storage device 424 (or one or more components thereof) may be removably interfaced with control system 112 (e.g., via an external port connector (not shown)). Particularly, storage device 424 and an associated machine-readable medium 428 may provide nonvolatile and/or volatile storage of machine-readable instructions, data structures, program modules, and/or other data for control system 112. In one example, software 420 may reside, completely or partially, within machine-readable medium 428. In another example, software 420 may reside, completely or partially, within processor 198.

Control system 112 may also include an input device 432. In one example, a user of control system 112 may enter commands and/or other information into computer system 112 via input device 432. Examples of an input device 432 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), touch screen, and any combinations thereof. Input device 432 may be interfaced to bus 412 via any of a variety of interfaces (not shown) including, but not limited to, a serial interface, a parallel interface, a game port, a USB interface, a FIREWIRE interface, a direct interface to bus 412, and any combinations thereof. Input device 432 may include a touch screen interface that may be a part of or separate from display 436, discussed further below. Input device 432 may be utilized as a user selection device for selecting one or more graphical representations in a graphical interface as described above.

Input device 432 may also include a sensor assembly or other suitable communications interface 433 for communicating with external sensors or inputs. In one exemplary embodiment, sensor assembly includes communications interface with probe 120 and/or pulse generator 116 to provide feedback as described herein regarding the sensed ground return indicative of dielectric material breakdown and related parameters. The output of probe 120 and/or pulse generator 116 can be stored, for example, in storage device 424 and can be further processed to provide, for example, an analysis of the time to breakdown of the dielectric material over time, by processor 198.

A user may also input commands and/or other information to control system 112 via storage device 424 (e.g., a removable disk drive, a flash drive, etc.) and/or network interface device 440. A network interface device, such as network interface device 440 may be utilized for connecting control system 112 to one or more of a variety of networks, such as network 444, and one or more remote devices 448 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network, a telephone network, a data network associated with a telephone/voice provider, a direct connection between two computing devices, and any combinations thereof. A network, such as network 444, may employ a wired and/or a wireless mode of communication. In general, any network topology may be used. Information (e.g., data, software 420, etc.) may be communicated to and/or from control system 112 via network interface device 440.

Control system 112 may further include a video display adapter 452 for communicating a displayable image to a display device, such as display device 436. Examples of a display device include, but are not limited to, a liquid crystal display (LCD), a cathode ray tube (CRT), a plasma display, a light emitting diode (LED) display, and any combinations thereof. Display adapter 452 and display device 436 may be utilized in combination with processor 198 to provide a graphical representation of a utility resource, a location of a land parcel, and/or a location of an easement to a user. In addition to a display device, control system 112 may include one or more other peripheral output devices including, but not limited to, an audio speaker, a printer, and any combinations thereof. Such peripheral output devices may be connected to bus 412 via a peripheral interface 456. Examples of a peripheral interface include, but are not limited to, a serial port, a USB connection, a FIREWIRE connection, a parallel connection, and any combinations thereof.

Persons of ordinary skill in the art will appreciate that the present invention and its application are not limited to the specific embodiments described above for purposes of exemplifying embodiments of the invention. For example, while liquid dielectrics such as mineral oil are commonly selected as a dielectric material, persons of ordinary skill in the art will appreciate based on the teachings set forth herein that embodiments of the present invention are not limited to use with liquid dielectrics. Dielectric fluids comprising gas, or dielectric solid materials also may be monitored and tested via embodiments of the present invention. Additionally, while field monitoring of in-service equipment is an area of important need for the present invention, embodiments of the invention may also be used for non-destructive testing of dielectric material samples, for example in a bench-top or laboratory setting. Persons of ordinary skill in the art will recognize that in the case of such testing, embodiments of the present invention may be utilized essentially unchanged from the description above other than the probe element being removed from specific equipment and configured to hold a material sample within the gap as is otherwise known in the art. Fluid samples in this regard may be contained in a suitable container between the needle and ground plane (parabolic-shaped) electrodes.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A system for determining a state of a dielectric material used in dielectric-containing electrical equipment, the system comprising:
a probe defining a gap configured to receive the dielectric material therein; and
a pulse generator in electrical communication with said probe, the pulse generator configured to produce a negative voltage pulse at said gap.

2. The system of claim 1, further comprising a control system in electronic communication with said pulse generator, the control system configured to initiate generation of said negative voltage pulse by the pulse generator and to provide output indicative of the dielectric material state based on a return signal from said probe.

3. The system of claim 2, wherein said control system comprises a processor configured to execute instructions to:
direct said pulse generator to generate said negative voltage pulse;
evaluate a signal from said pulse generator, said signal including information regarding a ground return from said probe resulting from at least a portion of said negative voltage pulse passing across said gap; and
determine the dielectric material state including at least a breakdown time based upon the ground return signal.

4. The system of claim 1, wherein the probe comprises a needle and a ground plane with said gap defined therebetween.

5. The system of claim 4, wherein the ground plane is ogive-shaped with the pointed end toward the gap.

6. The system of claim 5, wherein the ogive shape comprises parabolic curves.

7. The system of claim 1, wherein the negative voltage pulse comprises a substantially square waveform.

8. The system of claim 7, wherein the negative voltage pulse is a variable pulse.

9. The system of claim 7, wherein said negative voltage is between about −10 kV and about −30 kV.

10. The system of claim 9, wherein said negative voltage is between about −15 kV and about −30 kV.

11. The system of claim 1, wherein the system is configured to determine the state of a dielectric material that is a fluid.

12. The system of claim 11, wherein the fluid is a liquid.

13. The system of claim 1, wherein the fluid is a gas.

14. The system of claim 12, wherein the dielectric-containing electrical equipment comprises fluid-filled equipment and wherein said probe is configured and dimensioned to mount within the fluid-filled equipment in communication with the fluid contained therein.

15. The system of claim 12, wherein the fluid-filled equipment comprises a power transformer.

16. The system of claim 1, wherein the system is configured to determine the state of a dielectric material that is a solid.

17. The system of claim 1, wherein said probe and said gap are configured and dimensioned to receive a discrete sample of dielectric material.

18. The system of claim 17, wherein said dielectric material is a fluid contained in a container.

19. The system of claim 17, wherein said dielectric material is a solid.

20. A system for determining a state of dielectric material in dielectric-containing electrical equipment, comprising:
a probe configured and dimensioned to mount within the equipment in communication with the dielectric material contained therein, said probe including a needle and a ground plane;
a pulse generator including a voltage multiplier, said voltage multiplier electronically coupled to said probe; and
a control system in electronic communication with said pulse generator, wherein said control system includes instructions to:
direct said pulse generator to generate a substantially square negative voltage pulse;
evaluate a signal from said pulse generator, said signal including information regarding a ground return resulting from at least a portion of said substantially square voltage pulse passing from said needle to said ground plane; and
determine the dielectric material state including at least a breakdown time based upon the ground return signal.

21. The system of claim 20, wherein the dielectric material is a fluid.

22. The system of claim 21, wherein the dielectric-containing electrical equipment comprises fluid-filled equipment and wherein said probe is configured and dimensioned to mount within the fluid-filled equipment in communication with the fluid contained therein.

23. The system of claim 20, wherein the dielectric material is a solid.

24. The system of claim 20, wherein said needle and said ground plane are disposed in an opposing relationship so as to form a gap therebetween.

25. The system of claim 24, wherein said probe has an adjustable gap width.

26. The system of claim 24, wherein the ground plane has a parabolic shape.

27. The system of claim 26, wherein the ground plane comprises a parabolic ogive.

28. The system of claim 20, wherein said pulse generator senses said ground return via said ground plane.

29. The system of claim 20, wherein:
said pulse generator includes a power supply; and
said power supply is electronically coupled to said voltage multiplier so as to direct an AC voltage or a pulsed DC voltage to said voltage multiplier.

30. The system of claim 20, wherein said voltage multiplier comprises a ladder network of capacitors and diodes.

31. The system of claim 30, wherein said pulse generator produces a variable negative voltage pulse.

32. The system of claim 31, wherein said variable negative voltage is between about −10 kV and about −30 kV.

33. The system of claim 32, wherein said variable negative voltage is between about −15 kV and about −30 kV.

34. A method for testing a dielectric fluid within fluid-filled equipment, wherein the equipment includes a probe having a needle and a ground plane diametrically opposed within so as to form a testing gap, the method comprising:
generating a negative voltage waveform having a substantially square profile;
sending the voltage waveform to the needle;
monitoring for a ground return of at least a portion of the voltage through the testing gap to the ground plane;
determining, when said monitoring indentifies the ground return, a time the ground return occurred.

35. The method according to claim 34, further comprising determining a condition of the dielectric fluid based on said determining a time.

36. A method for testing a dielectric fluid within a power transformer, the method comprising:
delivering a negative DC voltage with a predetermined waveform to a probe positioned in the dielectric fluid inside the power transformer;
monitoring for a ground return at an electrode disposed in the dielectric fluid in the transformer at a predetermine distance from the probe; and
determining, when said monitoring indentifies the ground return, a time the ground return occurred.

37. A method for testing dielectric material, comprising:
relatively positioning the dielectric material within a gap formed by a needle electrode and ground plane;
generating a negative voltage waveform having a substantially square profile;
sending the negative voltage waveform to the needle;
monitoring for a ground return of at least a portion of the negative voltage through the said gap to the ground plane;
measuring, when said monitoring identifies the ground return, a time the ground return occurred; and
determining a condition of the dielectric material based on said measured time.

38. The method of claim 37, wherein said needle electrode and ground plane comprise a probe and said relatively positioning comprises mounting said probe within a dielectric-containing electrical equipment.

39. The method of claim 38, wherein said dielectric material is a fluid.

40. The method of claim 37, further comprising forming said ground plane with a parabolic curve.

41. The method of claim 40, wherein the parabolic curve comprises an ogive-shaped electrode.

42. The method of claim 37, wherein the negative voltage is between about −10 kV and about −30 kV.

43. The method of claim 42, wherein the negative voltage is between about −15 kV and about −30 kV.

44. The method of claim 39, wherein the fluid is a liquid.

45. The method of claim 39, wherein the fluid is a gas.

46. The method of claim 37, wherein the dielectric material is a solid.

47. The method of claim 37, wherein said relatively positioning comprises placing a discrete sample of dielectric material within the gap.

48. The method of claim 47, wherein said dielectric material is a fluid contained in a container.

49. The system of claim 47, wherein said dielectric material is a solid.

50. The method of claim 37, further comprising adjusting the gap to a specific width before said relatively positioning.

51. The method of claim 50, wherein said adjusting is based on at least one of the type of dielectric material, a type of equipment using the dielectric material, a point in the life-cycle of the equipment.

52. The method of claim 37, wherein said determining comprises correlating said measured time to predetermined dielectric material states.

53. The method of claim 37, wherein said method comprises a method for monitoring dielectric material state, said method further comprising:
instructing generation of the negative voltage wave form with a predetermined pulse length;
determining if a ground return received in less time than said predetermined pulse length;
when no ground return is received, identifying a good state for the dielectric material and instructing a new generation step at a first predetermined frequency interval;
when a ground return is received in a time less than the predetermined pulse length but greater than a second time value greater than zero, identifying a caution state for the dielectric material and instructing a new generation step at a second predetermined frequency interval;
when a ground return is received in a time less than the second time value, identifying an alert state for the dielectric material.

54. The method of claim 53, further comprising, when an alert state is identified, instructing a new generation step at a third predetermined frequency interval.

55. The method of claim 53, wherein said first predetermined frequency interval is the same as the second predetermined frequency interval.

56. The method of claim 53, wherein said first predetermined frequency interval is greater than the second predetermined frequency interval.
